(19) United States
(12) Patent Application Publication
(10) Pub. No.: US 2020/0261877 A1
(43) Pub. Date: Aug. 20, 2020

(54) METHOD FOR FORMING LIPID MEMBRANE VESICLE AND MICROREACTOR CHIP

(71) Applicant: THE UNIVERSITY OF TOKYO, Tokyo (JP)

(72) Inventors: Rikiya WATANABE, Tokyo (JP); Naoki SOGA, Tokyo (JP); Hiroyuki NOJI, Tokyo (JP)

(73) Assignee: THE UNIVERSITY OF TOKYO, Tokyo (JP)

(21) Appl. No.: 16/624,769

(22) PCT Filed: Apr. 19, 2018
(86) PCT No.: PCT/JP2018/016069

§ 371 Date: Mar. 26, 2020

(30) Foreign Application Priority Data
Jul. 5, 2017 (JP) 2017-131882

(51) Int. Cl. B01J 13/06; B01J 19/00; B01L 3/00

(52) U.S. Cl. CPC B01J 13/06; B81B 1/00; B01L 3/5085; B01J 19/0046

(57) ABSTRACT

A method for forming a lipid membrane vesicle includes: filling a chamber with a first aqueous solution by introducing it to a liquid flow path facing a microreactor chip hydrophobic layer main surface; forming a first lipid monolayer membrane in an opening part of the chamber filled with the solution; forming a second lipid monolayer membrane on a layer interface of the organic solvent formed on the main surface of the hydrophobic layer with a second aqueous solution by introducing the solution to the liquid flow path; allowing a first aqueous solution form in the chamber to alter to a spherical droplet covered with the first lipid monolayer membrane; and forming a lipid membrane vesicle by moving the droplet to a position of the second lipid monolayer membrane by applying a physical action, and by zipping the first lipid monolayer membrane covering the droplet and the second lipid monolayer membrane.

### TECHNICAL FIELD

The present invention relates to a method for forming a lipid membrane vesicle, and to a microreactor chip.

### BACKGROUND

JP 2015-040754 A (Patent Literature 1) discloses a high-density micro-chamber array provided with: a flat substrate; a plurality of micro-chambers, each having a capacity of not greater than 4,000×10⁻¹⁸ m³, that are formed from a hydrophobic material, and are arranged regularly at a high density on a surface of the substrate; and a lipidbilayermembrane that is formed at opening parts of the plurality of micro-chambers filled with an aqueous test solution to liquid-seal the aqueous test solution.

### SUMMARY

On the basis of the above-described conventional high-density micro-chamber array, development of the application technique has been desired.

A method for forming a lipid membrane vesicle according to one aspect of the present disclosure is provided with:

a step of filling each of a plurality of chambers with a first aqueous solution by introducing the first aqueous solution to a liquid flow path facing a main surface of a hydrophobic layer of a microreactor chip, in which the microreactor chip is provided with a substrate, and the hydrophobic layer being a layer made of a hydrophobic substance and arranged on the substrate, and opening parts of the chambers are formed so as to be regularly arranged on the main surface of the layer;

a step of forming a first lipid monolayer membrane in each of the opening parts of the chambers each filled with the first aqueous solution by introducing an organic solvent including a lipid to the liquid flow path to wash the first aqueous solution out of the liquid flow path except for the chambers;

a step of forming a second lipid monolayer membrane on an interface of a layer of the organic solvent formed on the main surface of the hydrophobic layer with a second aqueous solution by introducing the second aqueous solution to the liquid flow path;

a step of allowing a form of the first aqueous solution in each of the chambers to alter to a spherical droplet covered with the first lipid monolayer membrane; and

a step of forming a lipid membrane vesicle by moving the droplet covered with the first lipid monolayer membrane to a position of the second lipid monolayer membrane by applying a physical action to the microreactor chip, and by zipping the first lipid monolayer membrane covering the droplet and the second lipid monolayer membrane.

### BRIEF DESCRIPTION OF DRAWINGS

FIG. 1 is a plan view showing an example of a schematic configuration of a microreactor chip that is used in a method for forming a lipid membrane vesicle according to a first embodiment.

FIG. 2 is a diagram showing a cross section taken along the line A-A of the microreactor chip shown in FIG. 1.

FIG. 3 is a flowchart showing an example of a method for producing the microreactor chip shown in FIG. 1.

FIG. 4A is a diagram for illustrating a method for producing the microreactor chip shown in FIG. 1, and is a diagram showing a step of preparing a substrate.

FIG. 4B is a diagram for illustrating a method for producing the microreactor chip shown in FIG. 1, and is a diagram showing a step of forming a substance membrane on a substrate.

FIG. 4C is a diagram for illustrating a method for producing the microreactor chip shown in FIG. 1, and is a diagram showing a step of forming a resist on a substance membrane.

FIG. 4D is a diagram for illustrating a method for producing the microreactor chip shown in FIG. 1, and is a diagram showing a step of patterning a resist.

FIG. 4E is a diagram for illustrating a method for producing the microreactor chip shown in FIG. 1, and is a diagram showing a step of etching a substance membrane by using a patterned resist as a mask.

FIG. 4F is a diagram for illustrating a method for producing the microreactor chip shown in FIG. 1, and is a diagram showing a step of removing a resist.

FIG. 5 is a flowchart showing an example of a method for forming a lipid membrane vesicle according to a first embodiment.

FIG. 6 is a diagram for illustrating an example of a method for forming a lipid membrane vesicle according to a first embodiment, and is a diagram showing a step (Step S11) of introducing a first aqueous solution to a liquid flow path.

FIG. 7 is a diagram for illustrating an example of a method for forming a lipid membrane vesicle according to a first embodiment, and is a diagram showing a step (Step S12) of forming a first lipid monolayer membrane by introducing an organic solvent to a liquid flow path.

FIG. 8 is a diagram for illustrating an example of a method for forming a lipid membrane vesicle according to a first embodiment, and is a diagram showing a step (Step S13) of forming a second lipid monolayer membrane by introducing a second aqueous solution to a liquid flow path.

FIG. 9 is a diagram for illustrating an example of a method for forming a lipid membrane vesicle according to a first embodiment, and is a diagram enlarging and showing one of the chambers after forming a second lipid monolayer membrane.

FIG. 10 is a diagram for illustrating an example of a method for forming a lipid membrane vesicle according to a first embodiment, and is a diagram showing a step (Step S14) of allowing a form of a first aqueous solution in a chamber to alter to a droplet covered with a first lipid monolayer membrane.

FIG. 11 is a diagram for illustrating an example of a method for forming a lipid membrane vesicle according to a first embodiment, and is a diagram showing a step (Step S15) of forming a lipid membrane vesicle by allowing a droplet covered with a first lipid monolayer membrane to rise up.

FIG. 12 is a flowchart showing an example of a method for forming a lipid membrane vesicle according to a second embodiment.

FIG. 13 is a diagram for illustrating an example of a method for forming a lipid membrane vesicle according to a second embodiment, and is a diagram showing a step (Step S16) of forming a lipid membrane vesicle by allowing a second lipid monolayer membrane to descend.

FIG. 14 is a fluorescence image of a lipid membrane vesicle.

FIG. 15 is a graph showing a particle diameter distribution of lipid membrane vesicles for each capacity of chambers.

FIG. 16 is a graph showing a relationship between a volume of a lipid membrane vesicle and a capacity of a chamber.

FIG. 17 is a diagram for illustrating a method for measuring a substrate transport activity using a model protein of a lipid membrane vesicle.

FIG. 18 is a graph showing measurement results of substrate transport activity using a model protein of a lipid membrane vesicle.

### DESCRIPTION OF EMBODIMENTS

In various reactions of biomolecules, generating via a lipid bilayer membrane, for example, reactions in a membrane transport process and membrane transmission, and an enzyme reaction on a surface of a membrane, for example, it takes a long time to diffuse a reaction product, or changes in concentration of a substance with the enzyme activity are extremely moderate, and therefore, it tends to be difficult to detect various reactions of biomolecules generating via a lipid bilayer membrane with high sensitivity. If the capacity of the chamber is large, a change in the concentration in the chamber is small, and it is difficult to detect the concentration change. In a case where the number of chambers is small, the measurement throughput becomes worse. Therefore, a high-density micro-chamber array, in which a large number of micro-chambers with an extremely small capacity liquid-sealed by a lipid bilayer membrane are formed at a high density, is required. The above-described Patent Literature 1 discloses such a high-density micro-chamber array. However, there has been an unexamined part with respect to the application technique.

The present inventors have conducted intensive studies so as to find an application technique of a conventional high-density micro-chamber array. As a result, the following findings have been obtained. Note that the following findings serve only as a trigger of the present invention, and do not limit the present invention.

That is, with the development of the high-density micro-chamber array, it has become possible to efficiently perform measurement of, for example, transport of a transmembrane-type substance by a membrane protein. By the way, lipid membrane vesicles (also referred to as liposomes) having a uniform particle diameter have been regarded as a technical basis of basic research that contributes to medical care and drug discovery, and in recent years, from the viewpoint of the biocompatibility, the development of application to the medical care and drug discovery has been strongly expected.

As a conventional method for forming a lipid membrane vesicle, an inverse emulsion method (S. Pautot et al., 2003 Langmuir), or a hydration/electroformation method (G. Girard et al., 2004 Biophys. J) is known, however, by such a method, lipid membrane vesicles having a uniform size cannot be formed.

In K. Funakoshi et al., 2007 JACS, a method for forming lipid membrane vesicles having a uniform size has been proposed, however, by this method, enormous vesicles each having a diameter of 100 μm to 300 μm can only be formed. Because of the size, it has been considered difficult to apply the method to the medical care and drug discovery such as function evaluation of a membrane protein by using a lipid membrane vesicle, or a drug delivery system (DDS) for transporting a drug to the details of the human body. Therefore, it has been strongly desired to develop a method for forming lipid membrane vesicles having a small and uniform particle diameter that is smaller than the inner diameter of the capillary vessel (<5 μm).

On the basis of such an insight, the inventors have newly developed a lipid membrane vesicle array having a uniform particle diameter, which has been advanced from a conventional high-density micro-chamber array, and a method for producing the lipid membrane vesicle array. Specifically, although a microreactor chip that is the same as the conventional high-density micro-chamber array is used, by newly developing a formation protocol of a lipid membrane, a “technique for mass producing and arraying spherical fine liquid droplets having a uniform size”, and a “technique for covering a surface of a fine liquid droplet with a lipid membrane” are established, that is, mass production of lipid membrane vesicles having a uniform particle diameter and each covered with a lipid membrane has succeeded.

In addition, in the technique, the size of a micro-chamber of a microreactor chip is matched with the size of the lipid membrane vesicle to be formed. Therefore, by strictly defining the volume of the micro-chamber with the use of a semiconductor production process, the size of the lipid membrane vesicle can be quantitatively controlled up to the size of submicrometer.

Along with the uniformity and significant reduction in size of the lipid membrane vesicle, the use of the technique not only enables “i) highly sensitive and quantitative functional analysis of membrane proteins” and “ii) construction of an in vitro artificial reconstitution system that mimics cells”, which contribute to medical care and drug discovery, but also shows a path to “iii) quantitative evaluation of drug efficacy of DDS and the practical application”, which have been considered difficult from the past. That is, with the development of the technique, the versatility of an artificial membrane vesicle can be drastically expanded in the drug discovery and medical field.

Embodiments described below are created on the basis of the findings as described above.

A method for forming a lipid membrane vesicle according to a first aspect of an embodiment includes:

a step of filling each of a plurality of chambers with a first aqueous solution by introducing the first aqueous solution to a liquid flow path facing a main surface of a hydrophobic layer of a microreactor chip, in which the microreactor chip is provided with a substrate, and the hydrophobic layer being a layer made of a hydrophobic substance and arranged on the substrate, and opening parts of the of chambers are formed so as to be regularly arranged on the main surface of the layer;

a step of forming a first lipid monolayer membrane in each of the opening parts of the chambers each filled with the first aqueous solution by introducing an organic solvent including a lipid to the liquid flow path to wash the first aqueous solution out of the liquid flow path except for the chambers;

a step of forming a second lipid monolayer membrane on an interface of a layer of the organic solvent formed on the main surface of the hydrophobic layer with a second aqueous solution by introducing the second aqueous solution to the liquid flow path;

a step of allowing a form of the first aqueous solution in each of the chambers to alter to a spherical droplet covered with the first lipid monolayer membrane; and

a step of forming a lipid membrane vesicle by moving the droplet covered with the first lipid monolayer membrane to a position of the second lipid monolayer membrane by applying a physical action to the droplet, and by zipping the first lipid monolayer membrane covering the droplet and the second lipid monolayer membrane.

According to such an aspect, an aqueous solution filled in each chamber is covered with a lipid membrane to form a lipid membrane vesicle, and therefore, the size of the lipid membrane vesicle can be quantitatively controlled corresponding to the volume of the chamber, and as a result, the size of the lipid membrane vesicle can be drastically reduced and further made uniform. As a result, the concentration change of a reaction product, a reactant or the like in a lipid membrane vesicle due to reaction of one biomolecule is increased, the detection sensitivity when detecting as a concentration change can be increased, and even if the reaction of the biomolecule is extremely slow, the reaction of the biomolecule can be detected with high sensitivity. In addition, a double-layer membrane organelle, or a bacterial cell membrane is artificially constructed in vitro, and therefore, it becomes possible to analyze the function of a membrane protein present in the double-layer membrane organelle or bacterial cell membrane, which has been difficult to measure conventionally. Further, in addition to the reduction and uniformity in size of lipid membrane vesicles, a drug can be easily encapsulated in the inner part of the vesicle, and by using the vesicle as a carrier for DDS, the quantitative evaluation of drug efficacy and the practical application can be expected.

A method for forming a lipid membrane vesicle according to a second aspect of an embodiment is the method for forming a lipid membrane vesicle according to the first aspect, and

the physical action is any one of vibration, heat, electricity, and light.

A method for forming a lipid membrane vesicle according to a third aspect of an embodiment includes:

a step of filling each of a plurality of chambers with a first aqueous solution by introducing the first aqueous solution to a liquid flow path facing a main surface of a hydrophobic layer of a microreactor chip, in which the microreactor chip is provided with a substrate, and the hydrophobic layer being a layer made of a hydrophobic substance and arranged on the substrate, and opening parts of the plurality of chambers are formed so as to be regularly arranged on the main surface of the layer;

a step of forming a first lipid monolayer membrane in each of the opening parts of the chambers each filled with the first aqueous solution by introducing an organic solvent including a lipid to the liquid flow path to wash the first aqueous solution out of the liquid flow path except for the chambers;

a step of forming a second lipid monolayer membrane on an interface of a layer of the organic solvent formed on the main surface of the hydrophobic layer with a second aqueous solution by introducing the second aqueous solution to the liquid flow path;

a step of allowing a form of the first aqueous solution in each of the chambers to alter to a spherical droplet covered with the first lipid monolayer membrane; and

a step of forming a lipid membrane vesicle by moving the second lipid monolayer membrane to a position of the droplet by dissolving the organic solvent in the second aqueous solution, and by zipping the first lipid monolayer membrane covering the droplet and the second lipid monolayer membrane.

Even in such an aspect, an aqueous solution filled in each chamber is covered with a lipid membrane to forma lipid membrane vesicle, and therefore, the size of the lipid membrane vesicle can be quantitatively controlled corresponding to the volume of the chamber, and as a result, the size of the lipid membrane vesicle can be drastically reduced and further made uniform. As a result, the concentration change of a reaction product, a reactant or the like in a lipid membrane vesicle due to reaction of one biomolecule is increased, the detection sensitivity when detecting as a concentration change can be increased, and even if the reaction of the biomolecule is extremely slow, the reaction of the biomolecule can be detected with high sensitivity. Further, a double-layer membrane organelle or a bacterial cell membrane is artificially constructed in vitro, and therefore, it becomes possible to analyze the function of a membrane protein present in the double-layer membrane organelle or bacterial cell membrane, which has been difficult to measure conventionally. Further, in addition to the reduction and uniformity in size of lipid membrane vesicles, a drug can be easily encapsulated in the inner part of the vesicle, and by using the vesicle as a carrier for DDS, the quantitative evaluation of drug efficacy and the practical application can be expected.

A method for forming a lipid membrane vesicle according to a fourth aspect of an embodiment is the method for forming a lipid membrane vesicle according to any one of the first to third aspects, and

each of the plurality of chambers has a capacity of 4,000×10⁻¹⁸ m³ or less.

A method for forming a lipid membrane vesicle according to a fifth aspect of an embodiment is the method for forming a lipid membrane vesicle according to any one of the first to fourth aspects, and

the lipid membrane vesicle has a size corresponding to the capacity of each of the plurality of chambers.

A method for forming a lipid membrane vesicle according to a sixth aspect of an embodiment is the method for forming a lipid membrane vesicle according to any one of the first to fifth aspects, and

the lipid membrane vesicle has a diameter of 5 μm or less.

A microreactor chip according to a seventh aspect of an embodiment includes:

a substrate; and

a hydrophobic layer being a layer made of a hydrophobic substance and arranged on the substrate, in which opening parts of a plurality of chambers are formed so as to be regularly arranged on a main surface of the layer,

in which

a plurality of lipid membrane vesicles are formed on an interface of an organic solvent layer provided on the main surface of the hydrophobic layer on the opposite side to the hydrophobic layer.

A microreactor chip according to an eighth aspect of an embodiment includes:

a substrate; and

a hydrophobic layer being a layer made of a hydrophobic substance and arranged on the substrate, in which opening parts of a plurality of chambers are formed so as to be regularly arranged on a main surface of the layer,

in which

a lipid membrane vesicle is formed in each of the chambers.

A microreactor chip according to a ninth aspect of an embodiment is the method for forming a lipid membrane vesicle according to the seventh or eighth aspect, and each of the plurality of chambers has a capacity of 4,000×10⁻¹⁸ m³ or less.

A microreactor chip according to a tenth aspect of an embodiment is the method for forming a lipid membrane vesicle according to any one of the seventh to ninth aspects, and

the lipid membrane vesicle has a size corresponding to the capacity of each of the plurality of chambers.

A microreactor chip according to an eleventh aspect of an embodiment is the method for forming a lipid membrane vesicle according to any one of the seventh to tenth aspects, and

the lipid membrane vesicle has a diameter of 5 μm or less.

A method for incorporating an inclusion in a cell membrane vesicle, according to a twelfth aspect of an embodiment includes:

a step of filling each of a plurality of chambers with a first aqueous solution including a drug by introducing the first aqueous solution to a liquid flow path facing a main surface of a hydrophobic layer of a microreactor chip, in which the microreactor chip is provided with a substrate, and the hydrophobic layer being a layer made of a hydrophobic substance and arranged on the substrate, and opening parts of the chambers are formed so as to be regularly arranged on the main surface of the layer;

a step of forming a first lipid monolayer membrane in each of the opening parts of the chambers each filled with the first aqueous solution by introducing an organic solvent including a lipid to the liquid flow path to wash the first aqueous solution out of the liquid flow path except for the chambers;

a step of forming a second lipid monolayer membrane on an upper surface of a layer of the organic solvent formed on the main surface of the hydrophobic layer by introducing a second aqueous solution to the liquid flow path;

a step of allowing a form of the first aqueous solution in each of the chambers to alter to a spherical droplet covered with the first lipid monolayer membrane; and

a step of forming a lipid membrane vesicle by moving the droplet covered with the first lipid monolayer membrane to a position of the second lipid monolayer membrane by applying a physical action to the microreactor chip, and by zipping the first lipid monolayer membrane covering the droplet and the second lipid monolayer membrane.

A method for incorporating an inclusion in a cell membrane vesicle, according to a thirteenth aspect of an embodiment includes:

a step of filling each of a plurality of chambers with a first aqueous solution including a drug by introducing the first aqueous solution to a liquid flow path facing a main surface of a hydrophobic layer of a microreactor chip, in which the microreactor chip is provided with a substrate, and the hydrophobic layer being a layer made of a hydrophobic substance and arranged on the substrate, and opening parts of the chambers are formed so as to be regularly arranged on the main surface of the layer;

a step of forming a first lipid monolayer membrane in each of the opening parts of the chambers each filled with the first aqueous solution by introducing an organic solvent including a lipid to the liquid flow path to wash the first aqueous solution out of the liquid flow path except for the chambers;

a step of forming a second lipid monolayer membrane on an upper surface of a layer of the organic solvent formed on the main surface of the hydrophobic layer by introducing a second aqueous solution to the liquid flow path;

a step of allowing a form of the first aqueous solution in each of the chambers to alter to a spherical droplet covered with the first lipid monolayer membrane; and

a step of forming a lipid membrane vesicle by moving the second lipid monolayer membrane to a position of the droplet by dissolving the organic solvent in the second aqueous solution, and by zipping the first lipid monolayer membrane covering the droplet and the second lipid monolayer membrane.

Hereinafter, specific examples of the embodiments will be described in detail with reference to the accompanying drawings. In this regard, in each of the drawings, the constituent having the same function is denoted by the same reference numeral, and the detailed description of the constituent having the same reference numeral will not be repeated.

### First Embodiment

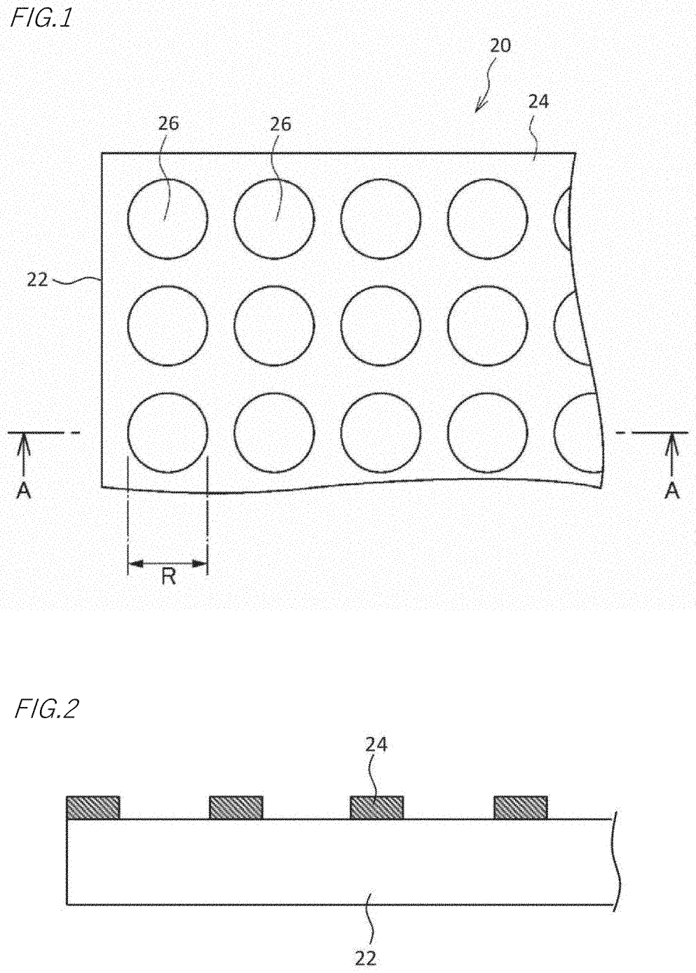

FIG. 1 is a view showing an example of a schematic configuration of a microreactor chip that is used in a method for forming a lipid membrane vesicle according to a first embodiment. FIG. 2 is a diagram showing a cross section taken along the line A-A of the microreactor chip shown in FIG. 1.

As shown in FIGS. 1 and 2, a microreactor chip 20 is provided with a substrate 22, and a hydrophobic layer 24 arranged on the substrate 22.

The substrate 22 has translucency and is flat. The substrate 22 can be constituted of, for example, a glass, or an acrylic resin. The material, thickness, shape and the like of the substrate 22 are not particularly limited as long as a light entering the substrate 22 from below the substrate 22 can penetrate the substrate 22 and can enter an inner part of a chamber 26, and further a light entering the substrate 22 from the inner part of the chamber 26 can penetrate the substrate 22 and can escape below the substrate 22. Specifically, a thickness of the substrate 22 may be, for example, 0.1 mm or more and 5 mm or less, may also be 0.3 mm or more and 3 mm or less, or may also be 0.7 mm or more and 1.5 mm or less. The size of the substrate 22 in plan view is not particularly limited.

The hydrophobic layer 24 is a layer made of a hydrophobic substance. Examples of the hydrophobic substance include a hydrophobic resin such as a fluorine resin, and a substance other than a resin, such as glass. The thickness of the hydrophobic layer 24 can be appropriately adjusted corresponding to a capacity of a chamber 26 to be described later. Specifically, the thickness may be, for example, 10 nm or more and 100 μm or less, may also be 100 nm or more and 5 μm or less, or may also be 250 nm or more and 1 μm or less.

In the hydrophobic layer 24, opening parts of a plurality of micro-chambers 26 are formed so as to be regularly arranged at a high density on the main surface of the hydrophobic layer 24. The capacity of the chamber 26 is 4,000×10⁻¹⁸ m³ or less (4,000 μm³ or less). The capacity of the chamber 26 may be, for example, 0.1×10⁻¹⁸ m³ or more and 4,000×10⁻¹⁸ m³ or less, may also be 0.5×10⁻¹⁸ m³ or more and 400×10⁻¹⁸ m³ or less, or may also be 1×10⁻¹⁸ m³ or more and 40×10⁻¹⁸ m³ or less.

The depth of the chamber 26 may be, for example, 10 nm or more and 100 μm or less, may also be 100 nm or more and 5 μm or less, or may also be 250 nm or more and 1 μm or less.

The opening part of the chamber 26 can be made into, for example, a circular shape. The diameter of the circle in a case of a circular shape may be, for example, 0.1 μm or more and 100 μm or less, may also be 0.5 μm or more and 5 μm or less, or may also be 1 μm or more and 10 μm or less.

The term “regularly” means that, for example, as viewed from the thickness direction of a substrate, chambers are arranged on a substrate in a lattice pattern, a matrix pattern, a staggered pattern or the like. The term “regularly” can mean that, for example, chambers are arranged at regular intervals so as to form multiple rows.

The term “high density” means that the number of chambers per square mm (1 mm²) may be, for example, 0.1×10³ or more and 2,000×10³ or less, may also be 1×10³ or more and 1,000×10³ or less, or may also be 5×10³ or more and 100×10³ or less. In terms of 1 cm² (1×10⁻⁴ m²), the number of chambers may be 10×10³ or more and 200×10⁶ or less, may also be 100×10³ or more and 100×10⁶ or less, or may also be 0.5×10⁶ or more and 10×10⁶ or less.

In a microreactor chip 20, each of the plurality of chambers 26 can be formed so as to have a depth of 100 μm or less, and a diameter of 100 μm or less in terms of a circular shape, can also be formed so as to have a depth of 2 μm or less, and a diameter of 10 μm or less in terms of a circular shape, or can also be formed so as to have a depth of 1 μm or less, and a diameter of 5 μm or less in terms of a circular shape. In this way, a thin membrane of a hydrophobic substance is formed on a surface of a substrate 22, and by using a technique for forming multiple microscopic chambers 26 on the thin membrane, a microreactor chip 20 before forming a lipid bilayer membrane can be relatively easily produced. In this regard, the term “diameter” “in terms of a circular shape” means a diameter of a circle having the same area as the area of the cross section perpendicular to the depth direction, and for example, in a case where the cross section is a square with a 1 μm square area, a diameter in terms of a circular shape is 2/√π≈1.1 μm.

The chamber 26 can also be a chamber that is formed on a thin membrane of a hydrophobic substance having a thickness in a predetermined thickness range including 500 nm such that a diameter in terms of a circular shape can be in a predetermined diameter range including 1 μm. When considering the magnitude of the reaction rate of the biomolecule to be tested and the content of the biomolecule, and further when considering the ease of the production, it is considered that the depth and diameter of the chamber 26 are preferably several hundred nanometers to several micrometers. In this regard, the term “predetermined thickness range” can be set to, for example, a range of 50 nm or more of 0.1 time 500 nm and 5 μm or less of 10 times 500 nm, or can also be set to a range of 250 nm or more of 0.5 time 500 nm and 1 μm or less of twice 500 nm. The term “predetermined diameter range” can be set to, for example, 100 nm or more of 0.1 time 1 μm and 10 μm or less of 10 times 1 μm, or can also be set to a range of 500 nm or more of 0.5 time 1 μm and 2 μm or less of twice 1 μm.

In an example, each of chambers 26 is formed so as to have a diameter R of 5 μm in a hydrophobic layer 24 having a thickness D of 1 μm. Therefore, the capacity L of each of chambers 26 satisfies L=π(2.5×10⁻⁶)²×1×10⁻⁶ m³≈19.6×10⁻¹⁸ m³. Assuming that chambers 26 are arranged tentatively at intervals of 2 μm in longitudinal and transverse directions in plan view, the area S required for one chamber 26 is a square with sides of 7 μm, and is calculated as S=(7×10⁻⁶)² m²=49×10⁻¹² m². Therefore, in a glass substrate 22, around 2×10⁶ per 1 cm² (1×10⁻⁴ m²) (20×10³ per square mm) of chambers 26 are formed.

Although the illustration is omitted, in the inner part of each chamber 26 (for example, on an inner side surface or a bottom surface of a chamber 26), an electrode may be provided. Respective electrodes may be electrically connected with each other. The electrode may be constituted of a metal, for example, copper, silver, gold, aluminum, chromium, or the like. The electrode may be constituted of a material other than a metal, for example, indium tin oxide (ITO), a material including indium tin oxide and zinc oxide (IZO), ZnO, a material constituted of indium, gallium, zinc, and oxygen (IGZO), or the like.

The thickness of the electrode may be, for example, 10 nm or more and 100 μm or less, may also be 100 nm or more and 5 μm or less, or may also be 250 nm or more and 1 μm or less.

In such a constitution, a light entering a substrate 22 from below the substrate 22 penetrates the substrate 22 and enters an inner part of a chamber 26, and further a light entering a substrate 22 from the inner part of the chamber 26 penetrates the substrate 22 and escapes below the substrate 22.

### [Method for Producing Microreactor Chip]

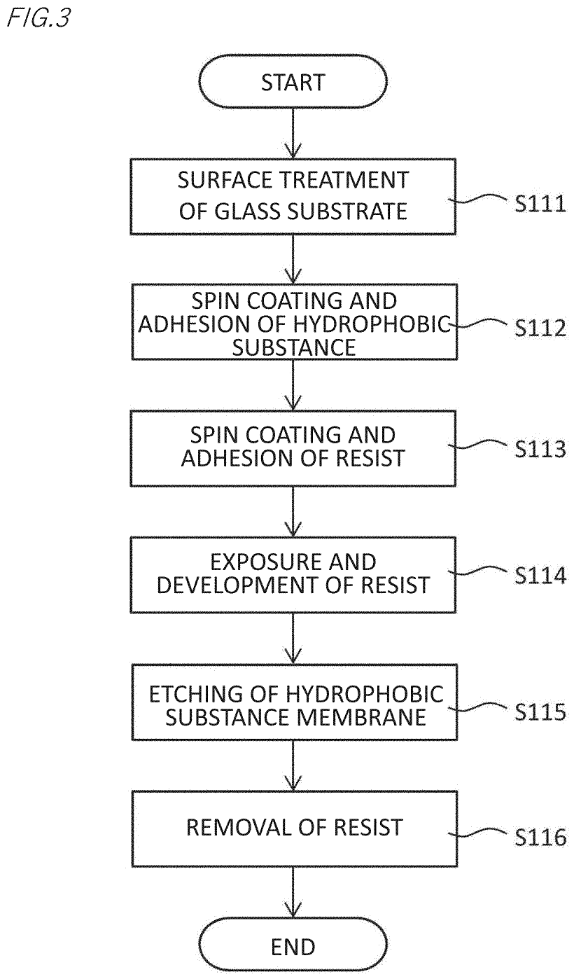

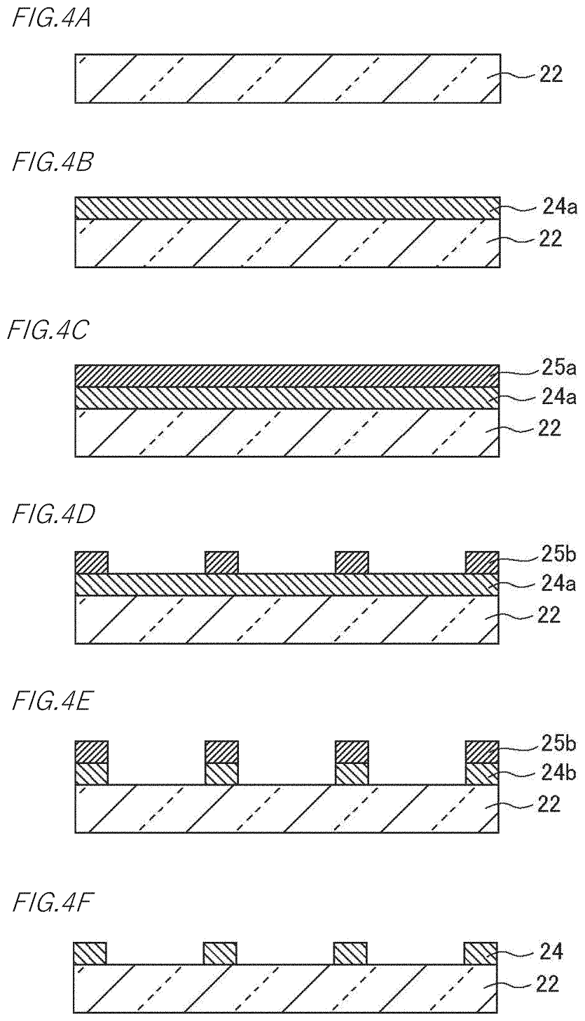

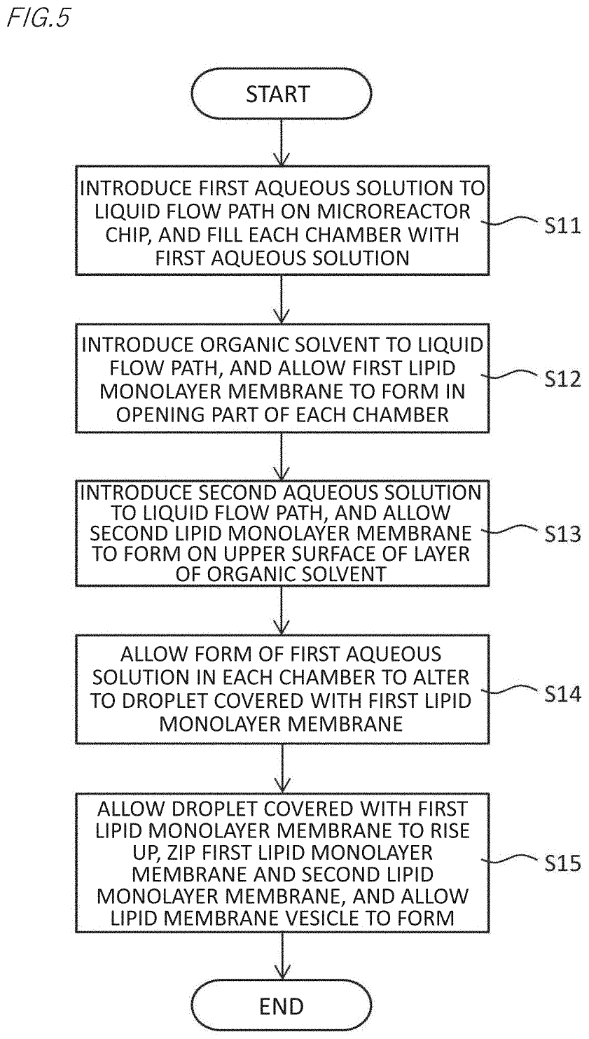

Next, with reference to FIGS. 3 and 4A to 4F, a method for producing a microreactor chip 20 will be described. FIG. 3 is a flowchart showing an example of a method for producing a microreactor chip 20. FIGS. 4A to 4F are diagrams showing respective steps in a method for producing a microreactor chip 20.

First, as shown in FIGS. 3 and 4A, as a cleaning treatment for cleaning a glass surface of a glass substrate 22, the glass substrate 22 is immersed in a 10 M potassium hydroxide (KOH) solution for around 24 hours (Step S111). In this way, the surface of the glass substrate 22 becomes hydrophilic.

Next, as shown in FIG. 4B, a hydrophobic substance (for example, fluorine resin (CYTOP) manufactured by ASAHI GLASS CO., LTD.) is spin-coated on the surface of the glass substrate 22 to form a substance membrane 24a, and the substance membrane 24a is brought into close contact with the surface of the glass substrate 22 (Step S112). As the conditions of the spin coating, for example, conditions of 2,000 rps and 30 seconds can be used, and in this case, the thickness of the substance membrane 24a is around 1 μm. The adhesion of the substance membrane 24a to the surface of the glass substrate 22 can be performed, for example, with the baking of 1 hour on a hot plate at 180° C.

Next, as shown in FIG. 4C, a resist 25a is formed on a surface of the substance membrane 24a by spin coating, and the resist 25a is brought into close contact with the surface of the substance membrane 24a (Step S113). As the resist 25a, AZ-4903 manufactured by AZ Electronic Materials plc can be used. As the conditions of the spin coating, for example, conditions of 4,000 rps and 60 seconds can be used. The adhesion of the resist 25a to the surface of the substance membrane 24a can be performed, for example, with the baking of 5 minutes on a hot plate at 110° C. for evaporating the organic solvent in the resist 25a.

Next, as shown in FIG. 4D, the resist 25a is exposed by using a mask of a pattern of chambers 26, immersed in a developing solution specialized for a resist, and is developed to form a resist 25b in which parts for forming chambers 26 are removed (Step S114). As the exposure condition, for example, a condition of irradiation with UV power of 250 W for 7 seconds by an exposure machine manufactured by SAN-EI ELECTRIC CO., LTD. can be used. As the development condition, for example, a condition of immersion in an AZ developer manufactured by AZ Electronic Materials plc for 5 minutes can be used.

Next, as shown in FIG. 4E, by dry-etching the substance membrane 24a masked by the resist 25b, parts to be chambers 26 are removed from the substance membrane 24a for obtaining a substance membrane 24b (Step S115), and then as shown in FIG. 5F, the resist 25b is removed (Step S116). For the dry etching, for example, a reactive ion etching device manufactured by Samco Inc. is used, and as the etching conditions, conditions of 50 sccm of O₂, a pressure of 10 Pa, a power of 50 W, and a time of 30 min can be used. The removal of the resist 25b can be performed with the immersion in acetone, the cleaning with isopropanol, and then the cleaning with pure water.

In this regard, by using a technique other than dry etching, for example, a technique of nanoimprinting or the like, a plurality of chambers 26 may be formed on a thin membrane of a hydrophobic substance. In a case of dry etching, an inner side surface of a chamber 26 becomes hydrophilic due to the action of O₂ plasma, and the chamber 26 is easily filled with an aqueous solution, and therefore, this dry etching is preferred.

### [Method for Forming Lipid Membrane Vesicle]

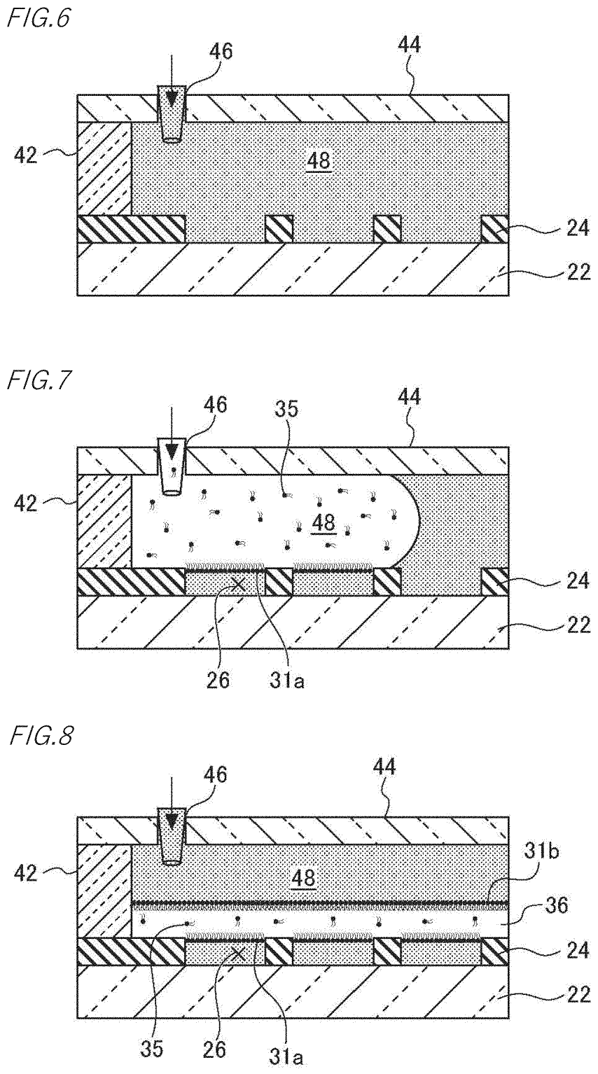

Next, with reference to FIGS. 5 to 11, a method for forming a lipid membrane vesicle according to a first embodiment will be described. FIG. 5 is a flowchart showing an example of a method for forming a lipid membrane vesicle according to the first embodiment. FIGS. 6 to 11 are diagrams showing respective steps in the method for forming a lipid membrane vesicle according to the first embodiment.

First, as shown in FIGS. 5 and 6, a glass plate 44 in which a liquid introduction hole 46 is formed is arranged by interposing a spacer 42 therebetween on a microreactor chip. With this arrangement, a liquid flow path 48 in which a main surface of a hydrophobic layer 24 is a substantially horizontal bottom surface is formed. Next, a first aqueous solution including a surfactant is introduced from the liquid introduction hole 46 to the liquid flow path 48, the liquid flow path 48 and the chambers 26 are filled with the first aqueous solution (Step S11). In this regard, as the first aqueous solution, specifically, for example, a mixture in which a fluorescent dye (for example, Alexa 488 (green)) having a final concentration of 10 μM is added into a liquid including 1 mM HEPES and 10 mM potassium chloride (hereinafter, may be referred to as “buffer solution A”) can be used. The first aqueous solution may include a drug to be contained in a lipid membrane vesicle.

Next, as shown in FIG. 7, in a state in which the liquid flow path 48 and the chambers 26 are filled with the first aqueous solution, an organic solvent having a specific gravity higher than that of the first aqueous solution and including lipids 35 is introduced from the liquid introduction hole 46 into the liquid flow path 48 (Step S12). In this regard, as the lipid, a natural lipid derived from a soybean or E. coli, or an artificial lipid such as dioleoylphosphatidylethanolamine (DOPE) or dioleoylphosphatidylglycerol (DOPG) can be used. As the organic solvent, chloroform can be used. As a specific example, a lipid including 1 mg/ml of DOPC and 0.045 mg/ml of a fluorescence lipid (for example, NBD-PS (green)) can be used.

When an organic solvent including lipids 35 is introduced from the liquid introduction hole 46 into the liquid flow path 48, in a state in which chambers 26 are filled with the first aqueous solution, a first lipid monolayer membrane 31a with a hydrophilic group of the lipid 35, the hydrophilic group facing the first aqueous solution side of the chamber 26, is formed so as to liquid-seal an opening part of the chamber 26. The first aqueous solution is washed away from the liquid flow path 48 other than the chambers 26.

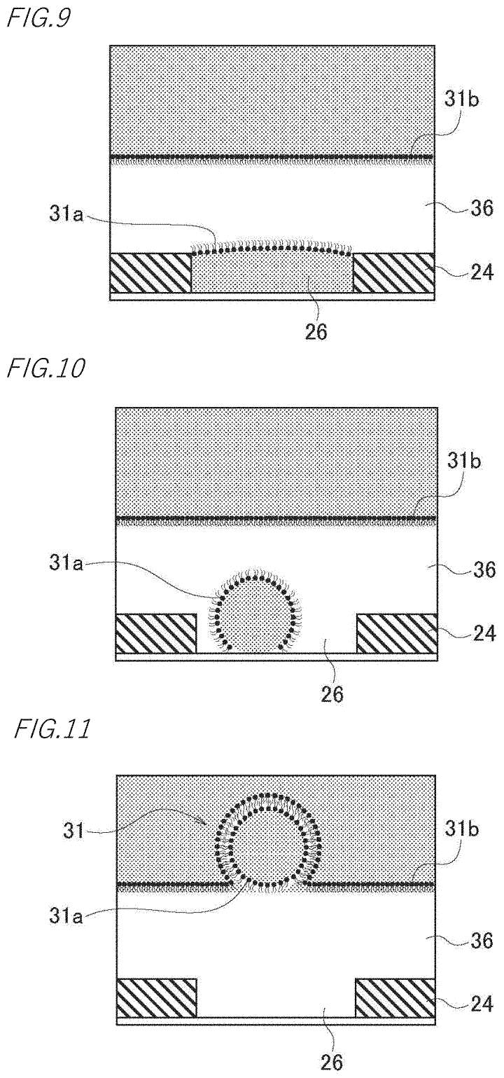

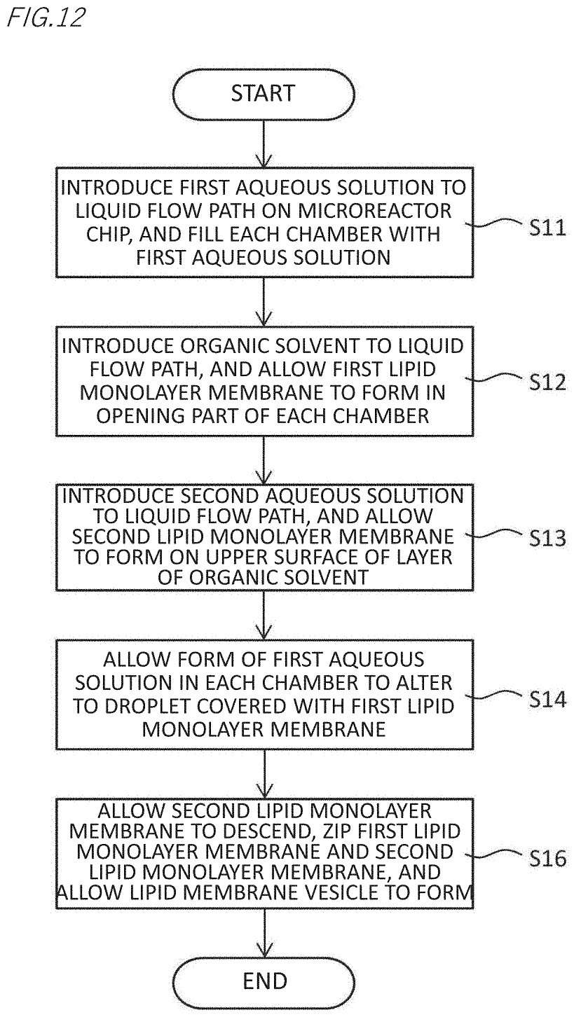

Next, as shown in FIG. 8, a second aqueous solution having a specific gravity lower than that of the organic solvent is introduced from the liquid introduction hole 46 into the liquid flow path 48 (Step S13). As the second aqueous solution, specifically, for example, a buffer solution A can be used.

When a second aqueous solution is introduced from the liquid introduction hole 46 into the liquid flow path 48, an organic solvent layer 36 is formed on a main surface of the hydrophobic layer 24, and a second lipid monolayer membrane 31b with a hydrophilic group of the lipid 35, the hydrophilic group facing the second aqueous solution side, is formed on an interface between the organic solvent layer 36 and the second aqueous solution.

Next, as shown in FIGS. 9 and 10, a form of the first aqueous solution in a chamber 26, which is liquid-sealed by the first lipid monolayer membrane 31a, is spontaneously altered to a spherical droplet covered with the first lipid monolayer membrane 31a due to the surface tension (Step S14). Since the first aqueous solution includes a surfactant, the first aqueous solution is easy to come off from the wall surface of the chamber 26 with hydrophilicity, and can be easily made into a spherical form spontaneously.

Next, as shown in FIG. 11, by applying a physical action to the droplet covered with the first lipid monolayer membrane 31a, the droplet is released from the wall surface of the chamber 26 and allowed to rise up to an upper surface of the organic solvent layer 36 (Step S15). The physical action is not particularly limited as long as the droplet covered with the first lipid monolayer membrane 31a can be released from the wall surface of the chamber 26, and the physical action is, for example, any one of vibration, heat, electricity, and light.

When the droplet covered with the first lipid monolayer membrane 31a reaches the upper surface of the organic solvent layer 36, the first lipid monolayer membrane 31a covering the droplet and the second lipid monolayer membrane 31b are zipped, that is, the second lipid monolayer membrane 31b is formed so as to overlap the outer side of the first lipid monolayer membrane 31a, and thus a lipid membrane vesicle 31 covered with a lipid bilayer membrane is formed. In this regard, in a case where the first aqueous solution includes a drug, the lipid membrane vesicle 31 contains the drug.

After the formation of the lipid membrane vesicle 31, a step of reconstituting a membrane protein in the lipid bilayer membrane of the lipid membrane vesicle 31 may also be provided. The step of reconstitution may also be a step of forming a membrane protein by introducing any one of a cell membrane fragment including a membrane protein, a lipid bilayer membrane into which a protein is embedded, a water-soluble protein, and a protein solubilized by a surfactant into a lipid bilayer membrane of a lipid membrane vesicle 31, and by incorporating the protein into the lipid bilayer membrane. As a technique for incorporating the protein into the lipid bilayer membrane, thermal fluctuation or the like can be employed in a case of a protein solubilized by a surfactant.

By the method as described above, a microreactor chip 20 in which multiple lipid membrane vesicles 31 are formed on an upper surface of an organic solvent layer 36 arranged on a main surface of a hydrophobic layer 24 can be obtained.

In this regard, a light entering a substrate 22 from below the substrate 22 penetrates the substrate 22 and enters an inner part of a chamber 26, and further a light entering a substrate 22 from the inner part of the chamber 26 penetrates the substrate 22 and escapes below the substrate 22. In a case where a membrane protein is reconstituted in a lipid membrane vesicle, the function of the membrane protein can be analyzed by detecting a light emitted from a fluorescent substance included in a first aqueous solution that is contained in the inner part of the lipid membrane vesicle, with the use of a confocal laser scanning microscope. As a microscope, a vertical illumination-type confocal microscope may be used.

### Examples

In Examples according to the first embodiment, the inventors prepared five kinds of microreactor chips A to E that have chambers 26 with different sizes as shown in the following Table 1.

TABLE 1

| | |
|---|---|
| Kind of | Size of chamber |

| microreactor chip | Opening diameter [μm] | Depth [nm] |
|---|---|---|
| A | 2 | 30 |
| B | 2 | 200 |
| C | 3 | 500 |
| D | 5.5 | 500 |
| E | 9 | 500 |

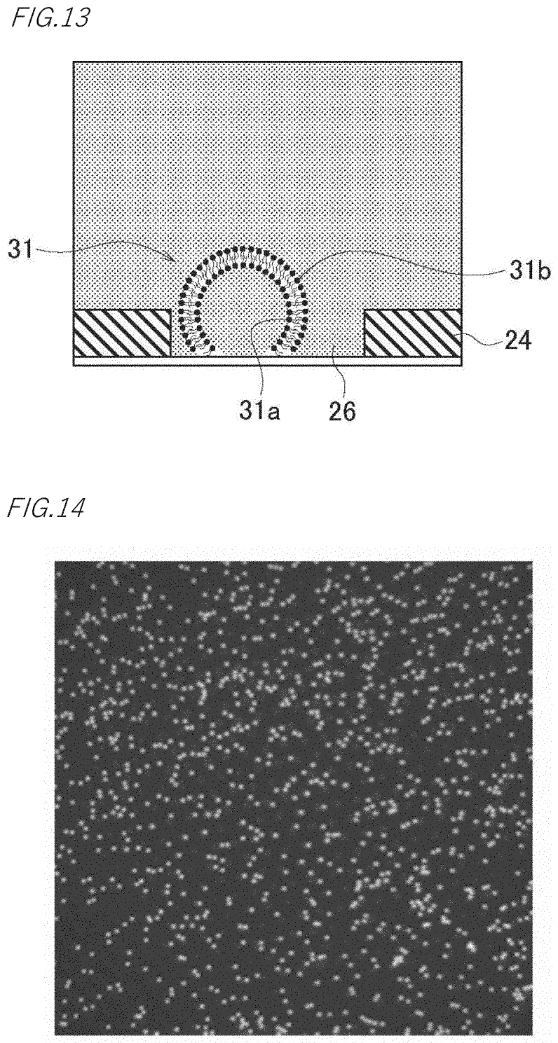

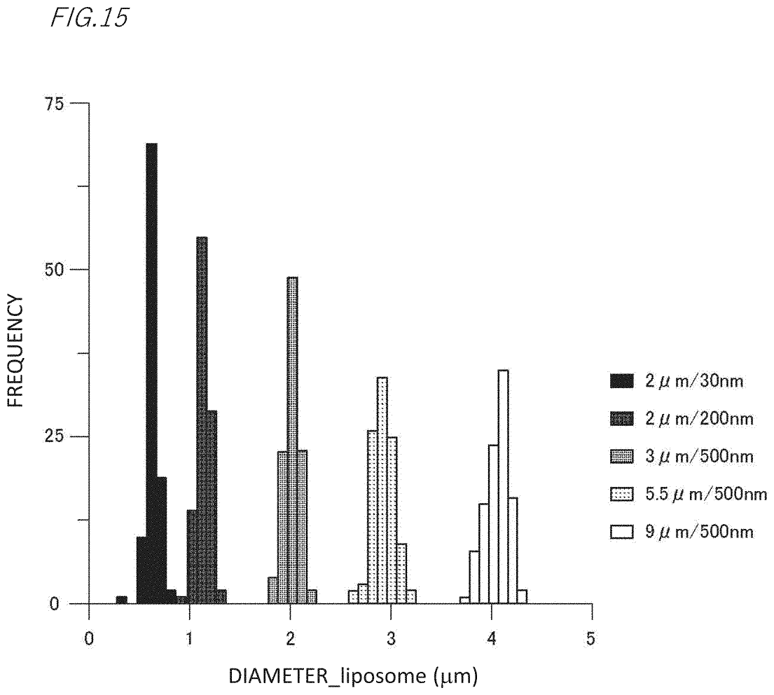

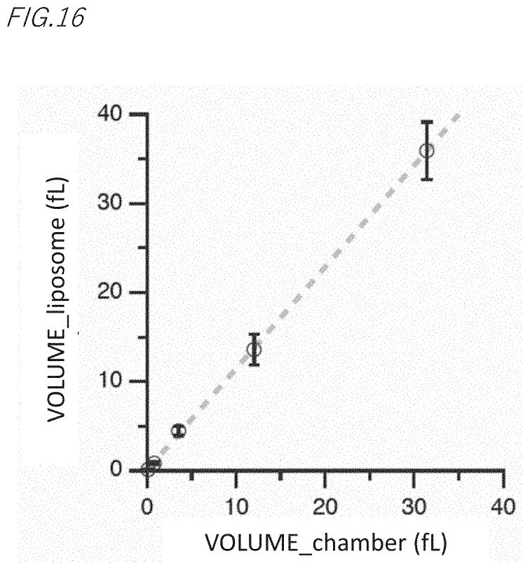

Next, the inventors formed lipid membrane vesicles 31 by performing a method for forming a lipid membrane vesicle according to a first embodiment for each of the microreactor chips. FIG. 14 shows a fluorescence image of lipid membrane vesicles 31 formed practically by the inventors.

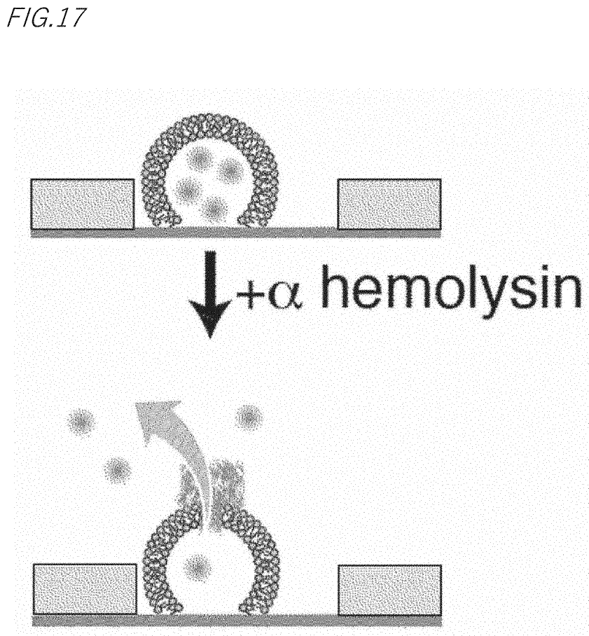

Further, the inventors measured the particle diameter of the formed lipid membrane vesicle 31 for each of the microreactor chips using the fluorescence image. FIG. 15 is a graph showing the particle diameter distribution of the lipid membrane vesicles 31 formed practically by the inventors for each size of the chambers 26. In addition, FIG. 16 is a graph showing the relationship between the volume of the lipid membrane vesicle 31 formed practically by the inventors and the capacity of a chamber 26.

As shown in FIG. 15, by the method for forming a lipid membrane vesicle according to the first embodiment, an ultrafine lipid membrane vesicle 31 having a diameter of 5 μm or less can be formed. Further, the particle diameter distribution of the lipid membrane vesicles 31 obtained for each size of the chambers 26 has a standard deviation of around 50 nm (uniformity of 10% or less), and thus extremely high uniformity can be achieved.

In addition, as shown in FIG. 16, the lipid membrane vesicle 31 has a volume corresponding to the capacity of a chamber 26. Therefore, by strictly defining the volume of a chamber 26 with the use of a semiconductor production process, the size of the lipid membrane vesicle 31 can be quantitatively controlled up to the size of submicrometer.

### Second Embodiment

Next, with reference to FIGS. 12 and 13, a method for forming a lipid membrane vesicle according to a second embodiment will be described. FIG. 12 is a flowchart showing an example of the method for forming a lipid membrane vesicle according to the second embodiment. FIG. 13 is a diagram showing a step (Step S16) of forming a lipid membrane vesicle in the method for forming a lipid membrane vesicle according to the second embodiment.

In the second embodiment, steps (Steps S11 to S14) of allowing a form of a first aqueous solution in each of the chambers 26 to alter to a droplet covered with a first lipid monolayer membrane 31a are the same as those of the first embodiment described above, and therefore, the descriptions are omitted.

In the second embodiment, after the step (Step S14) of allowing a form of a first aqueous solution in each of the chambers 26 to alter to a droplet covered with a first lipid monolayer membrane 31a, the resultant material was left to stand for a predetermined time (for example, around 15 minutes) to dissolve an organic solvent in a second aqueous solution. As the organic solvent is dissolved in the second aqueous solution, the organic solvent layer 36 becomes thinner, and the second lipid monolayer membrane 31b positioned on an upper surface of the organic solvent layer 36 descends (Step S15).

Further, the first lipid monolayer membrane 31a covering the droplet of chamber 26 and the descending second lipid monolayer membrane 31b are zipped, that is, the second lipid monolayer membrane 31b is formed so as to overlap the outer side of the first lipid monolayer membrane 31a, and thus a lipid membrane vesicle 31 covered with a lipid bilayer membrane is formed. In this regard, in a case where the first aqueous solution includes a drug, the lipid membrane vesicle 31 contains the drug.

After the formation of the lipid membrane vesicle 31, a step of reconstituting a membrane protein in the lipid bilayer membrane of the lipid membrane vesicle 31 may also be provided. The step of reconstitution may also be a step of forming a membrane protein by introducing any one of a cell membrane fragment including a membrane protein, a lipid bilayer membrane into which a protein is embedded, a water-soluble protein, and a protein solubilized by a surfactant into a lipid bilayer membrane of a lipid membrane vesicle 31, and by incorporating the protein into the lipid bilayer membrane. As a technique for incorporating the protein into the lipid bilayer membrane, thermal fluctuation or the like can be employed in a case of a protein solubilized by a surfactant.

By the method as described above, a microreactor chip 20 in which a lipid membrane vesicle 31 is formed in each of chambers 26 can be obtained.

### Examples

In Examples according to the second embodiment, the inventors formed a lipid membrane vesicle 31 in each of chambers 26 of a microreactor chip 20 by performing the method for forming a lipid membrane vesicle according to the second embodiment.

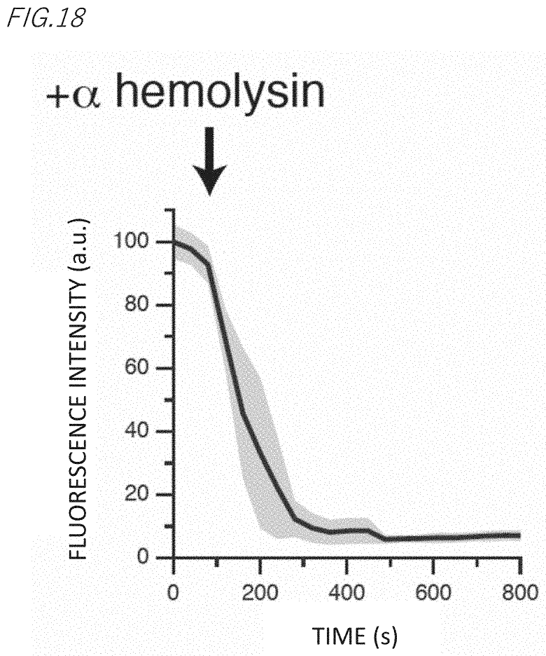

Next, as shown in FIG. 17, the inventors reconstituted α-hemolysin being a membrane transporter in a lipid bilayer membrane of the formed lipid membrane vesicle 31, and by using a fluorescence microscope, the substrate transport activity of the α-hemolysin was measured from the change in the intensity of a light emitted from a fluorescent substance contained in the lipid membrane vesicle 31. FIG. 18 is a graph showing measurement results.

As shown in FIG. 18, the fluorescence intensity is gradually decreased with the lapse of time, and therefore, it can be confirmed that the α-hemolysin being a membrane transporter is reconstituted in the lipid membrane vesicle 31, that is, it can be confirmed that the lipid membrane vesicle formed by the inventors is covered with the lipid bilayer membrane.

According to the first and second embodiments as described above, a first aqueous solution filled in each chamber 26 is covered with a lipid membrane and a lipid membrane vesicle 31 is formed, and therefore, the size of the lipid membrane vesicle 31 can be quantitatively controlled up to the size of submicrometer corresponding to the volume of a chamber 26.

The application of ultrafine lipid membrane vesicles having a uniform size in basic research, medical care, and drug discovery is shown below.

### (1) Highly Sensitive and Quantitative Functional Analysis of Membrane Protein (Basic Research)

In highly sensitive and quantitative functional analysis of a membrane protein using a lipid membrane vesicle, uniformity and reduction in the volume of a lipid membrane vesicle is essential, and by using the technique according to the embodiment described above, the following effects can be obtained.

1. Highly Sensitive and Quantitative Functional Measurement of Membrane Protein by Using Uniform Fine Lipid Membrane Vesicle as Test Tube

Functional analysis of a membrane protein (for example, membrane transporter), which has not been able to be measured due to the insufficient sensitivity and quantitativity in the conventional method, is realized.

2. High-Throughput Functional Measurement by Using Fine Lipid Membrane Vesicle in Parallel

Achievement of high-throughput contributes to a drug screening system based on functional analysis of a membrane protein.

### (2) Construction of Artificial Cell Mimicking Cell (Basic Research)

The size of a cell or an intracellular organelle varies from several tens of μm to several hundreds of nm depending on the kind, and in order to reconstruct these cell and intracellular organelle artificially, it is required to control the size of a lipid membrane vesicle strictly. By using the technique according to the embodiments described above, the following effects can be obtained.

1. Lipid Membrane Vesicle Controllable to the Same Size as in Cell

A lipid membrane vesicle that mimics an intracellular organelle, a bacterium or the like, which has been difficult to prepare by the conventional method, can be prepared.

### (3) Carrier of DDS System (Applied Research of Medical Care and Drug Discovery or the Like)

In DDS for delivering a drug, it is essential to make the carrier biocompatible, and to make the particle diameter small and uniform in order to perform the delivering to the details of the human body and to stabilize the effect. Further, it is required to easily encapsulate a drug in an inner part of a lipid membrane vesicle. For such a problem, by using the technique according to the embodiments described above, the following effects can be obtained.

1. Reduction in Size of Carrier, Capable of being Transported to Capillary Vessel

A drug can be delivered to the details of the human body through the capillary vessel having a diameter of 5 μm or less.

2. Achievement of Simple Preparation of Membrane Vesicle Constituted of Phospholipid Encapsulating Drug

A membrane vesicle, which has been considered difficult to prepare in the conventional DDS due to non-uniform size and poor encapsulation efficiency, can be easily prepared.

In this regard, in the embodiment described above, as shown in FIGS. 6 to 11 and 13, a lipid membrane vesicle 31 is formed with an aspect in which a liquid flow path 48 is arranged on the upper side of a microreactor chip 20, however, the formation of the lipid membrane vesicle 31 is not limited to the aspect, an aspect in which FIGS. 6 to 11 and 13 are turned upside down, that is, a lipid membrane vesicle 31 may be formed with an aspect in which a liquid flow path 48 is arranged on the lower side of a microreactor chip 20.

For example, as an modification example of the first Example, looking at FIGS. 6 to 11 upside down, (1) by introducing a first aqueous solution to a liquid flow path 48 facing a main surface of a hydrophobic layer 24 of a microreactor chip 20, the liquid flow path 48 and a chamber 26 are filled with the first aqueous solution, (2) by introducing an organic solvent including lipids, which has a specific gravity lower than that of the first aqueous solution, to the liquid flow path 48 to wash the first aqueous solution out of the liquid flow path 48 except for the chamber 26, a first lipid monolayer membrane 31a is formed in an opening part of the chamber 26 filled with the first aqueous solution, (3) by introducing a second aqueous solution, which has a specific gravity higher than that of the organic solvent, to the liquid flow path 48, a second lipid monolayer membrane 31b is formed on an interface of an organic solvent layer 36 formed on the main surface of the hydrophobic layer 24 with the second aqueous solution, (4) by allowing a form of the first aqueous solution in the chamber 26 to alter to a spherical droplet covered with the first lipid monolayer membrane 31a, (5) by applying a physical action to the droplet covered with the first lipid monolayer membrane 31a, the droplet is released from the wall surface of the chamber 26 and allowed to descend to a position of the second lipid monolayer membrane 31b, and by zipping the first lipid monolayer membrane 31a covering the droplet and the second lipid monolayer membrane 31b, a lipid membrane vesicle 31 may be formed.

In addition, as an modification example of the second Example, looking at FIGS. 6 to 10 and 13 upside down, (1) by introducing a first aqueous solution to a liquid flow path 48 facing a main surface of a hydrophobic layer 24 of a microreactor chip 20, the liquid flow path 48 and a chamber 26 are filled with the first aqueous solution, (2) by introducing an organic solvent including lipids, which has a specific gravity lower than that of the first aqueous solution, to the liquid flow path 48 to wash the first aqueous solution out of the liquid flow path 48 except for the chamber 26, a first lipid monolayer membrane 31a is formed in an opening part of the chamber 26 filled with the first aqueous solution, (3) by introducing a second aqueous solution, which has a specific gravity higher than that of the organic solvent, to the liquid flow path 48, a second lipid monolayer membrane 31b is formed on an interface of an organic solvent layer 36 formed on the main surface of the hydrophobic layer 24 with the second aqueous solution, (4) by allowing a form of the first aqueous solution in the chamber 26 to alter to a spherical droplet covered with the first lipid monolayer membrane 31a, (5) by dissolving an organic solvent in the second aqueous solution and thinning the organic solvent layer 36, the second lipid monolayer membrane 31b is allowed to rise up to a position of the droplet, and by zipping the first lipid monolayer membrane 31a covering the droplet and the second lipid monolayer membrane 31b, a lipid membrane vesicle 31 may be formed.

Note that the descriptions of the above-described embodiments and individual modification examples and the disclosure of the drawings are merely examples for describing the invention described in the scope of claims for patent, and the invention described in the scope of claims for patent is not limited by the descriptions of the above-described embodiments and individual modification examples or the disclosure of the drawings. The constituent elements of the above-described embodiments and individual modification examples can be arbitrarily combined without departing from the gist of the invention.

1. A method for forming a lipid membrane vesicle, comprising:
a step of filling each of a plurality of chambers with a first aqueous solution by introducing the first aqueous solution to a liquid flow path facing a main surface of a hydrophobic layer of a microreactor chip, wherein the microreactor chip is provided with a substrate, and the hydrophobic layer being a layer made of a hydrophobic substance and arranged on the substrate, and opening parts of the plurality of chambers are formed so as to be regularly arranged on the main surface of the layer;
a step of forming a first lipid monolayer membrane in each of the opening parts of the plurality of chambers each filled with the first aqueous solution by introducing an organic solvent including a lipid to the liquid flow path to wash the first aqueous solution out of the liquid flow path except for the plurality of chambers;
a step of forming a second lipid monolayer membrane on an interface of a layer of the organic solvent formed on the main surface of the hydrophobic layer with a second aqueous solution by introducing the second aqueous solution to the liquid flow path;
a step of allowing a form of the first aqueous solution in each of the plurality of chambers to alter to a spherical droplet covered with the first lipid monolayer membrane; and
a step of forming a lipid membrane vesicle by moving the droplet covered with the first lipid monolayer membrane to a position of the second lipid monolayer membrane by applying a physical action to the droplet, and by zipping the first lipid monolayer membrane covering the droplet and the second lipid monolayer membrane.

2. The method for forming a lipid membrane vesicle according to claim 1, wherein
the physical action is any one of vibration, heat, electricity, and light.

3. A method for forming a lipid membrane vesicle, comprising:
a step of filling each of a plurality of chambers with a first aqueous solution by introducing the first aqueous solution to a liquid flow path facing a main surface of a hydrophobic layer of a microreactor chip, wherein the microreactor chip is provided with a substrate, and the hydrophobic layer being a layer made of a hydrophobic substance and arranged on the substrate, and opening parts of the chambers are formed so as to be regularly arranged on the main surface of the layer;
a step of forming a first lipid monolayer membrane in each of the opening parts of the chambers each filled with the first aqueous solution by introducing an organic solvent including a lipid to the liquid flow path to wash the first aqueous solution out of the liquid flow path except for the chambers;
a step of forming a second lipid monolayer membrane on an interface of a layer of the organic solvent formed on the main surface of the hydrophobic layer with a second aqueous solution by introducing the second aqueous solution to the liquid flow path;
a step of allowing a form of the first aqueous solution in each of the chambers to alter to a spherical droplet covered with the first lipid monolayer membrane; and
a step of forming a lipid membrane vesicle by moving the second lipid monolayer membrane to a position of the droplet by dissolving the organic solvent in the second aqueous solution, and by zipping the first lipid monolayer membrane covering the droplet and the second lipid monolayer membrane.

4. The method for forming a lipid membrane vesicle according to claim 1, wherein
each of the plurality of chambers has a capacity of 4,000×10⁻¹⁸ m³ or less.

5. The method for forming a lipid membrane vesicle according to claim 1, wherein
the lipid membrane vesicle has a size corresponding to the capacity of each of the plurality of chambers.

6. The method for forming a lipid membrane vesicle according to claim 1, wherein
the lipid membrane vesicle has a diameter of 5 μm or less.

7. A macroreactor chip, comprising:
a substrate; and
a hydrophobic layer being a layer made of a hydrophobic substance and arranged on the substrate, wherein opening parts of a plurality of chambers are formed so as to be regularly arranged on a main surface of the layer,
wherein
a plurality of lipid membrane vesicles are formed on an interface of an organic solvent layer provided on the main surface of the hydrophobic layer on the opposite side to the hydrophobic layer.

8. A microreactor chip, comprising:
a substrate; and
a hydrophobic layer being a layer made of a hydrophobic substance and arranged on the substrate, wherein opening parts of a plurality of chambers are formed so as to be regularly arranged on a main surface of the layer,
wherein
a lipid membrane vesicle is formed in each of the chambers.

9. The microreactor chip according to claim 7 wherein
each of the plurality of chambers has a capacity of 4,000×10⁻¹⁸ m³ or less.

10. The microreactor chip according to claim 7, wherein
the lipid membrane vesicle has a size corresponding to the capacity of each of the plurality of chambers.

11. The microreactor chip according to claim 7, wherein
the lipid membrane vesicle has a diameter of 5 μm or less.

12. A method for incorporating an inclusion in a cell membrane vesicle, comprising:
a step of filling each of a plurality of chambers with a first aqueous solution including a drug by introducing the first aqueous solution to a liquid flow path facing a main surface of a hydrophobic layer of a microreactor chip, wherein the microreactor chip is provided with a substrate, and the hydrophobic layer being a layer made of a hydrophobic substance and arranged on the substrate, and opening parts of the chambers are formed so as to be regularly arranged on the main surface of the layer;
a step of forming a first lipid monolayer membrane in each of the opening parts of the chambers each filled with the first aqueous solution by introducing an organic solvent including a lipid to the liquid flow path to wash the first aqueous solution out of the liquid flow path except for the chambers;
a step of forming a second lipid monolayer membrane on an upper surface of a layer of the organic solvent formed on the main surface of the hydrophobic layer by introducing a second aqueous solution to the liquid flow path;
a step of allowing a form of the first aqueous solution in each of the chambers to alter to a spherical droplet covered with the first lipid monolayer membrane; and
a step of forming a lipid membrane vesicle by moving the droplet covered with the first lipid monolayer membrane to a position of the second lipid monolayer membrane by applying a physical action to the microreactor chip, and by zipping the first lipid monolayer membrane covering the droplet and the second lipid monolayer membrane.

13. A method for incorporating an inclusion in a lipid membrane vesicle, comprising:
a step of filling each of a plurality of chambers with a first aqueous solution including a drug by introducing the first aqueous solution to a liquid flow path facing a main surface of a hydrophobic layer of a microreactor chip, wherein the microreactor chip is provided with a substrate, and the hydrophobic layer being a layer made of a hydrophobic substance and arranged on the substrate, and opening parts of the chambers are formed so as to be regularly arranged on the main surface of the layer;
a step of forming a first lipid monolayer membrane in each of the opening parts of the chambers each filled with the first aqueous solution by introducing an organic solvent including a lipid to the liquid flow path to wash the first aqueous solution out of the liquid flow path except for the chambers;
a step of forming a second lipid monolayer membrane on an upper surface of a layer of the organic solvent formed on the main surface of the hydrophobic layer by introducing a second aqueous solution to the liquid flow path;
a step of allowing a form of the first aqueous solution in each of the chambers to alter to a spherical droplet covered with the first lipid monolayer membrane; and
a step of forming a lipid membrane vesicle by moving the second lipid monolayer membrane to a position of the droplet by dissolving the organic solvent in the second aqueous solution, and by zipping the first lipid monolayer membrane covering the droplet and the second lipid monolayer membrane.

14. The method for forming a lipid membrane vesicle according to claim 3, wherein
each of the plurality of chambers has a capacity of 4,000×10⁻¹⁸ m³ or less.

15. The method for forming a lipid membrane vesicle according to claim 3, wherein
the lipid membrane vesicle has a size corresponding to the capacity of each of the plurality of chambers.

16. The method for forming a lipid membrane vesicle according to claim 3, wherein
the lipid membrane vesicle has a diameter of 5 μm or less.

17. The microreactor chip according to claim 8, wherein
each of the plurality of chambers has a capacity of 4,000×10⁻¹⁸ m³ or less.

18. The microreactor chip according to claim 8, wherein
the lipid membrane vesicle has a size corresponding to the capacity of each of the plurality of chambers.

19. The microreactor chip according to claim 8, wherein
the lipid membrane vesicle has a diameter of 5 μm or less.
